(19) United States
(12) Patent Application Publication
(10) Pub. No.: US 2025/0364389 A1
(43) Pub. Date: Nov. 27, 2025

(54) PACKAGE STRUCTURE, SEMICONDUCTOR STRUCTURE, AND ELECTRONIC DEVICE

(71) Applicant: CXMT Corporation, Hefei City (CN)

(72) Inventors: Hengrong SHI, Hefei City (CN); Honglong SHI, Hefei City (CN); Rui LI, Hefei City (CN); Jingwei CHENG, Hefei City (CN); Xing ZHANG, Hefei City (CN); Qun LIU, Hefei City (CN)

(73) Assignee: CXMT Corporation, Hefei City (CN)

(21) Appl. No.: 18/966,531

(22) Filed: Dec. 3, 2024

Related U.S. Application Data
(63) Continuation of application No. PCT/CN2024/126273, filed on Oct. 22, 2024.

(30) Foreign Application Priority Data
May 27, 2024 (CN) 202410675094.6

(51) Int. Cl. H01L 23/498; H01L 23/00; H01L 25/065; H01L 25/18; H10B 80/00

(52) U.S. Cl. CPC H01L 23/49838; H01L 23/49811; H01L 24/48; H01L 25/0657; H01L 25/18; H10B 80/00; H01L 2224/48225; H01L 2225/0651; H01L 2225/0652; H01L 2924/1431; H01L 2924/14361

(57) ABSTRACT

A package structure, a semiconductor structure, and an electronic device are disclosed. The package structure includes: a base; a first pin array, disposed on the base, where the first pin array includes a plurality of first data pins; and a second pin array, disposed on the base, where the second pin array includes a plurality of second data pins. A blank region is disposed between the first pin array and the second pin array, the blank region extends from a center of the base to an edge of the base, an end part of the blank region is outside the first pin array, at least one of the first data pins and/or at least one of the second data pins are/is adjacent to the blank region, and a minimum dimension of the blank region is greater than a diameter of the first data pin.

### CROSS REFERENCE TO RELATED APPLICATIONS

This application is a continuation of International Patent Application No. PCT/CN2024/126273 filed on Oct. 22, 2024, which claims priority to Chinese Patent Application No. 202410675094.6 filed on May 27, 2024. The disclosures of the above-referenced applications are hereby incorporated by reference in their entirety.

### BACKGROUND

With the advancement of science and technology, terminal users hope that the devices they use are smaller, faster in computing, more energy-saving, and have higher performance. Therefore, the miniaturization and versatility of electronic terminal products become a major trend of industrial development.

In some implementations, an existing package structure is relatively large in size, and cannot be applied to miniaturized electronic devices.

### SUMMARY

Embodiments of the present disclosure relate to the field of semiconductor technologies, and in particular, to a package structure, a semiconductor structure, and an electronic device.

According to a first aspect of the embodiments of the present disclosure, a package structure is provided and includes:
a base;
a first pin array, disposed on the base, where the first pin array includes a plurality of first data pins; and
a second pin array, disposed on the base, where the second pin array includes a plurality of second data pins;
where a blank region is disposed between the first pin array and the second pin array, the blank region extends from a center of the base to an edge of the base, an end part of the blank region is outside the first pin array, at least one first data pin is adjacent to the blank region and/or at least one second data pin is adjacent to the blank region, and a minimum dimension of the blank region is greater than a diameter of the first data pin.

According to a second aspect of the embodiments of the present disclosure, a semiconductor structure is provided, including the foregoing package structure and a die disposed on the package structure.

According to a third aspect of the embodiments of the present disclosure, a semiconductor structure is provided, including:
a circuit board, where a first die is disposed on the circuit board, a blank area is disposed on the circuit board, and a metal wire is disposed on a surface of the blank area;
the foregoing package structure, disposed on the circuit board, where a blank region in the package structure corresponds to the blank area; and
a second die, disposed on the package structure.

### BRIEF DESCRIPTION OF THE DRAWINGS

FIG. 1 is a schematic diagram of a semiconductor structure according to an example embodiment;

FIG. 2 is a top view of FIG. 1 according to an example embodiment;

FIG. 3 is a rear view of FIG. 1 according to an example embodiment;

FIG. 4 is a cross-sectional view of FIG. 3 in the A-A direction according to an example embodiment;

FIG. 5 is a schematic diagram of a package structure according to an example embodiment;

FIG. 6 is a schematic diagram of pins according to an example embodiment;

FIG. 7 is a schematic diagram of a blank region according to an example embodiment;

FIG. 8 is a schematic diagram of pin pitch according to an example embodiment;

FIG. 9 is another schematic diagram of pins according to an example embodiment;

FIG. 10 is another schematic diagram of pins according to an example embodiment;

FIG. 11 is a diagram of an overall structural of a base according to an example embodiment;

FIG. 12 is a schematic diagram of a pin architecture according to an example embodiment;

FIG. 13 is another schematic diagram of a semiconductor structure according to an example embodiment;

FIG. 14 is a schematic diagram of an electronic device according to an example embodiment;

FIG. 15 is a top view of FIG. 14 according to an example embodiment;

FIG. 16 is a diagram of plastic strain comparison of package substrates according to an example embodiment; and

FIG. 17 is a diagram of test performance comparison of package substrates

according to an example embodiment.

### DETAILED DESCRIPTION

The technical solutions of the present disclosure are further described below in detail with reference to the accompanying drawings and the embodiments. Although example implementations of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. A plurality of sublayers may be included in the layer.

It should be noted that the technical solutions described in the embodiments of the present disclosure may be arbitrarily combined when there is no conflict.

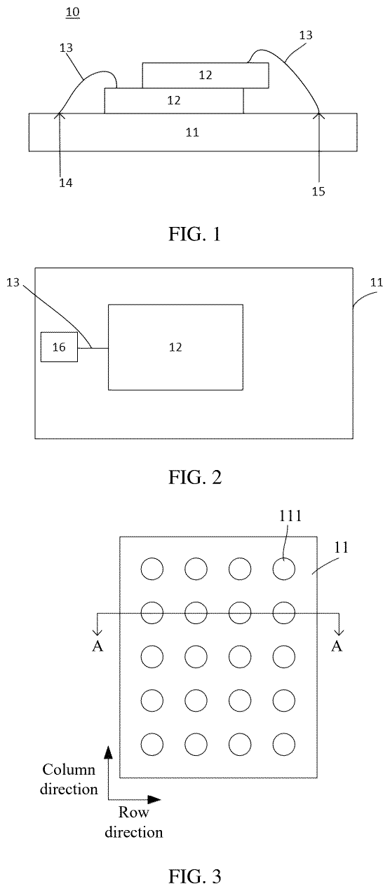

As shown in FIG. 1, an embodiment of the present disclosure provides a semiconductor structure 10. The semiconductor structure 10 includes a package substrate 11 and memory dies 12. A plurality of memory dies 12 are disposed on the package substrate 11, for example, two, four, eight, or more memory dies 12 may be disposed. These memory dies 12 are stacked. For example, two memory dies 12 in FIG. 1 are stacked, and the upper memory die 12 is disposed on and offset to the lower memory die 12. The memory die 12 may include a plurality of memory units connected to a word line and a bit line. For example, each of the plurality of memory units may be or correspond to a dynamic random access memory (DRAM) unit, and the memory die 12 is, for example, a low power double data rate SDRAM (LPDDR), for example, a fifth generation low power double data rate memory (LPDDR5/5X).

As shown in FIG. 1, the memory die 12 is connected to the package substrate 11 through a gold wire 13, so as to implement signal transmission. Each memory die 12 corresponds to one signal channel (channel). For example, the lower memory die 12 corresponds to a first signal channel 14 (Channel A, CHA), and the upper memory die 12 corresponds to a second signal channel 15 (Channel B, CHB). The first signal channel 14 and the second signal channel 15 each have independent data signals, chip select signals, clock enable signals, and the like. Therefore, the first signal channel 14 and the second signal channel 15 are relatively independent. When the semiconductor structure 10 is applied, a memory controller can send data signals to the memory dies 12 through a data bus, a data signal is transmitted to the lower memory die 12 through the first signal channel 14 and the gold wire 13, and a data signal is transmitted to the upper memory die 12 through the second signal channel 15 and the gold wire 13.

As shown in FIG. 1 and FIG. 2, FIG. 2 is a simplified top view of FIG. 1. A pad 16 is disposed on a front side of the package substrate 11, and the pad 16 is disposed on, for example, an edge of the package substrate 11. The gold wire 13 connects the pad 16 and the memory die 12, so as to implement signal transmission. In some embodiments, a same pad 16 may alternatively be connected to a plurality of memory dies 12, that is, connected to a plurality of memory dies 12 through a plurality of gold wires 13, so that one signal channel is connected to a plurality of memory dies 12.

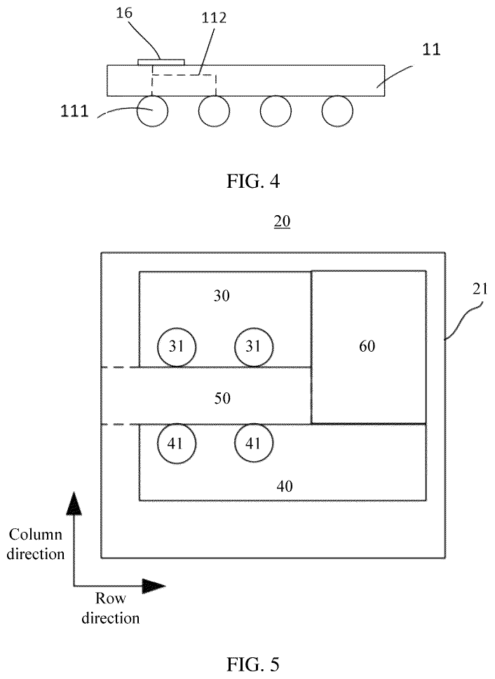

As shown in FIG. 3 and FIG. 4, FIG. 3 is a schematic diagram of a back side of the package substrate 11, and FIG. 4 is a cross-sectional view of FIG. 3 in a direction of A-A. A plurality of pins 111 are disposed on the back side of the package substrate 11, and the pins 111 may be disposed in an array. The pin 111 may be a solder ball or a bump. These pins 11 may transmit different signals, for example, may transmit signals such as a data signal (Data Quality, DQ) and a chip select (CS) signal. The pin 111 is connected to the pad 16 through an internal wire 112 in the package substrate 11, and then the pad 16 is connected to the memory die 12 through the gold wire 13, so as to transmit a signal to the memory die 12. In some embodiments, there are a large quantity of pins 111 (for example, 315 pins), and a pitch (Pitch) between the pins 111 is relatively large, resulting in a large overall package volume of the semiconductor structure 10, which cannot be adapted to a miniaturized electronic product.

As shown in FIG. 5, an embodiment of the present disclosure provides a package structure 20. The package structure 20 may be the foregoing package substrate 11. The package structure 20 has a relatively small quantity of pins, and a pitch between the pins is reduced, so that a volume of the package structure 20 can be reduced, and the package structure 20 can be applied to a miniaturized electronic product. In this embodiment of the present disclosure, the pins are further rearranged, so that the package structure 20 has good performance, and the package structure 20 can provide good signal transmission for a die, ensuring normal operation of the die.

As shown in FIG. 5, this embodiment of the present disclosure provides a package structure 20. The package structure 20 includes a base 21, a first pin array 30, a second pin array 40, and a third pin array 60. The first pin array 30, the second pin array 40, and the third pin array 60 are located on the base 21, for example, may be disposed on a back side of the base 21. A blank region 50 is disposed between the first pin array 30 and the second pin array 40, and no pin is disposed in the blank region 50. That is, the first pin array 30 and the second pin array 40 are separated by the blank region 50. The blank region 50 extends from a center of the base 21 to an edge of the base 21, and an end part of the blank region 50 is outside the first pin array 30. That is, in the row direction, the length of the blank region 50 is greater than the length of the first pin array 30. In addition, in the row direction, the length of the blank region 50 is greater than the length of the second pin array 40. A plurality of first signal pins 31 are disposed in the first pin array 30, and a plurality of second signal pins 41 are disposed in the second pin array 40. The first signal pin 31 and the second signal pin 41 are both adjacent to the blank region 50. Therefore, when the package structure 20 is installed on a PCB, the blank region 50 forms a corresponding blank area on the PCB, and the first signal pin 31 and the second signal pin 41 are adjacent to the blank area. In this way, wires may be arranged in the blank area, and the wire is connected to the first signal pin 31 and the second signal pin 41, so as to perform signal transmission.

As shown in FIG. 5, in this embodiment of the present disclosure, in the row direction, the length of the blank region 50 is greater than the length of the first pin array 30. In the column direction, a minimum dimension of the blank region 50 is greater than the diameter of the first signal pin 31, and the minimum dimension of the blank region 50 is greater than a pitch (Pitch) between two adjacent first signal pins 31. From this point of view, the blank region 50 has a large area. Therefore, a large blank area is formed on the PCB, a plurality of wires are designed in the blank area, and a pitch between the wires increases, thereby reducing crosstalk between signals.

As shown in FIG. 5, in this embodiment of the present disclosure, at least one first signal pin 31 in the first pin array 30 is adjacent to the blank region 50, and at least one second signal pin 41 in the second pin array 40 is adjacent to the blank region 5. The first signal pin 31 and the second signal pin 41 may both be adjacent to the blank region 50. Certainly, either of the first signal pin 31 and the second signal pin 41 may be adjacent to the blank region 50.

As shown in FIG. 4 and FIG. 5, in this embodiment of the present disclosure, a pad 16 is disposed on a front side of the base 21, an internal wire 112 is disposed in the base 21, and the internal wire 112 is connected to the pad 16. In addition, the internal wire 112 is further connected to the first signal pin 31, the second signal pin 41, or another pin, so as to implement signal transmission.

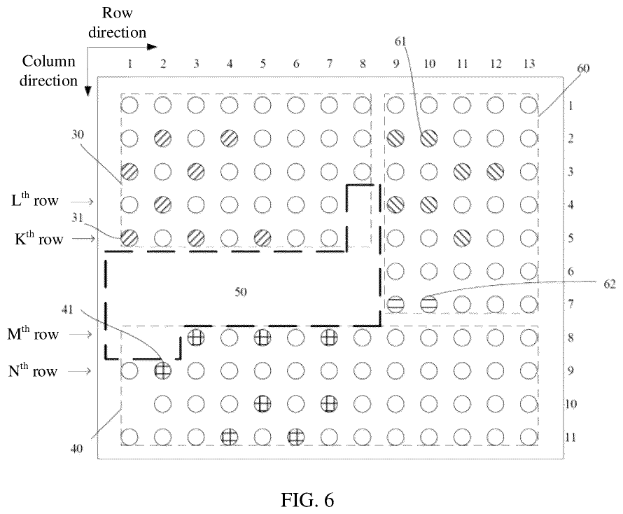

As shown in FIG. 6, FIG. 6 shows a diagram of the back side of the base 21. The first pin array 30 is located at an upper left part of the base 21, the second pin array 40 is located at a lower part of the base 21, and the third pin array 60 is located at a lower part of the base 21. A blank region 50 exists between the first pin array 30 and the second pin array 40, and no pin is disposed in the blank region 50. Therefore, the first pin array 30 and the second pin array 40 may be separated by the blank region 50. In the row direction (horizontal direction), the first pin array 30 has eight columns of pins. In the column direction (vertical direction), the first pin array 30 has five rows of pins. The first pin array 30 may include a maximum of 40 pins. However, to facilitate wiring for pins in the third pin array 60, some pins are removed from the first pin array 30. For example, two pins are removed from the first pin array 30. In this case, the first pin array 30 includes 38 pins. In this embodiment, two pins in a column (the eighth column of the first pin array 30) adjacent to the third pin array 60 in the first pin array 30 are removed. Because the quantity of pins is reduced, the area of the blank region 50 is increased, that is, an area for wiring is increased on the PCB.

As shown in FIG. 6, a plurality of first signal pins 31 are disposed in the first pin array 30, and at least one pin may be disposed between the first signal pins 31. For example, in the first column, one pin is disposed between two first signal pins 31. In the second row, one pin is disposed between two first signal pins 31. In this embodiment, the first signal pin 31 may be configured to transmit a high-bandwidth data signal (Data Quality, DQ). During transmission of a DQ signal, the first signal pin 31 generates a magnetic field. If two first signal pins 31 are contiguously disposed, generated magnetic fields overlap between the two signal pins, and an overlapping magnetic field induces an electrical flow in the first signal pin 31, thereby generating signal crosstalk and reducing signal quality. As shown in FIG. 6, a first signal pin 31 may be adjacent to another first signal pin 31 on a diagonal line, that is, two first signal pins 31 are not contiguously disposed in a horizontal and vertical direction, thereby increasing diffusion space of a magnetic field, reducing magnetic field overlap, and reducing signal crosstalk.

As shown in FIG. 6, in this embodiment of the present disclosure, eight first signal pins 31 are disposed in the first pin array 30, and a relatively large quantity of first signal pins 31 are disposed in a row adjacent to the blank region 50 in the first pin array 30. The first row to the fifth row are adjacent in sequence, and the fifth row is adjacent to the blank region 50. Therefore, the fifth row is defined as the K^{th} row, and the fourth row adjacent to the fifth row is defined as the Lth row. In this case, a quantity of first signal pins 31 in the K^{th} row is greater than a quantity of first signal pins 31 in the Lth row, thereby facilitating wiring for more first signal pins 31. For example, three first signal pins 31 are disposed in the fifth row, one first signal pin 31 is disposed in the fourth row, two first signal pins 31 are disposed in the third row, and two first signal pins 31 are disposed in the second row. Because a largest quantity of first signal pins 31 are disposed in the fifth row, that is, more first signal pins 31 are adjacent to the blank region 50, thereby facilitating wiring for more first signal pins 31. In this embodiment of the present disclosure, positions of the first signal pins 31 are rearranged, so that the first signal pins 31 are relatively centralized, and are close to an edge of the base 21, thereby reducing a signal loss.

As shown in FIG. 6, in this embodiment of the present disclosure, the second pin array 40 is disposed on a side of the blank region 50, that is, the second pin array 40 and the first pin array 30 are located on opposite sides of the blank region 50. In the row direction, the second pin array 40 includes 13 columns of pins; and in the column direction, the second pin array 40 includes four rows of pins. The second pin array 40 includes a maximum of 52 pins. A quantity of pins in the second pin array 40 is greater than a quantity of pins in the first pin array 30, and the length of the second pin array 40 in the row direction is greater than the length of the first pin array 40 in the row direction. Therefore, to facilitate wiring for the pins in the second pin array 40, some pins in a row adjacent to the blank region 50 in the second pin array 40 are removed. In this embodiment of the present disclosure, pins close to a left edge of the base 21 in the eighth row are removed, that is, some pins adjacent to the blank region 50 are removed, so that the blank region 50 of a larger area is formed. In this way, the blank region 50 may be extended to the second pin array 40. Because the area of the blank region 50 is increased, it is conducive to wiring for the second signal pins 41 in the second pin array 40. In addition, in this embodiment of the present disclosure, a pin in the first column and the tenth row is also removed, so that the area of the blank region 50 is increased in disguise, which also helps wiring for the second signal pins 41.

As shown in FIG. 6, in this embodiment of the present disclosure, the second pin array 40 includes a plurality of second signal pins 41. For an arrangement manner of the second signal pins 41, refer to an arrangement manner of the first signal pins 31. An arrangement rule of the first signal pins 31 is applicable to an arrangement rule of the second signal pins 41. In this embodiment of the present disclosure, the second signal pin 41 is configured to transmit high-bandwidth signal data, and the second signal pin 41 is configured to transmit a high-bandwidth data signal (Data Quality, DQ). The second pin array 40 includes eight second signal pins 41, and a row adjacent to the blank region 40 in the second pin array 40 has a larger quantity of second signal pins 41. These second signal pins 41 are disposed in the eighth row to the eleventh row respectively, the eighth row to the eleventh row are adjacent in sequence, and the eighth row is adjacent to the blank region 50. There are three second signal pins 41 in the eighth row, one second signal pin 41 in the ninth row, two second signal pins 41 in the tenth row, and two second signal pins 41 in the eleventh row. A quantity of second signal pins 41 in the eighth row is greater than a quantity of second signal pins 41 in the ninth row. Therefore, it is conducive to wiring for more second signal pins 41. In this embodiment, the eighth row is defined as the M^{th} row, and the ninth row is defined as the N^{th} row. Therefore, a quantity of second signal pins 41 in the M^{th} row is greater than a quantity of second signal pins 41 in the N^{th} row. In addition, the blank region 50 extends into the second pin array 40, so that at least one second signal pin 41 in the ninth row (the N^{th} row) may be adjacent to the blank region 50, thereby facilitating wiring for the second signal pin 41. Certainly, by arranging the second signal pins 41 in the second pin array 40, more second signal pins 41 may be disposed in the N^{th} row, and more second signal pins 41 are adjacent to the blank region 50. It should be noted that, although the second signal pin 41 in the ninth row is adjacent to the blank region 50, there are still pins in the eighth row between other pins in the ninth row and the blank region 50. Therefore, in this embodiment, the ninth row is not defined as adjacent to the blank region 50.

As shown in FIG. 6, in this embodiment of the present disclosure, these second signal pins 41 are distributed relatively centrally, for example, distributed in the second column to the seventh column. In other words, in the row direction, the distance from a left edge of the base 21 to the second signal pin 41 (the second signal pin 41 in the seventh column) does not exceed the length of the blank region 50, so that wires for the second signal pins 41 can be shortened.

As shown in FIG. 6, in this embodiment of the present disclosure, the first signal pin 31 is configured to transmit a DQ signal, and the second signal pin 41 is configured to transmit a DQ signal. Therefore, some first signal pins 31 and some second signal pins 41 may be symmetrical about the blank region 50. For example, the first signal pins 31 (in the third column and the fifth column) in the fifth row and the second signal pins 41 (in the third column and the fifth column) in the eighth row are symmetrical, that is, the first signal pins and the second signal pins are disposed opposite to each other. Therefore, wires of the first signal pins 31 and wires of the second signal pins 41 may be symmetrical, and a wiring process is relatively simple. Certainly, the first signal pin 31 (in the first column) in the fifth row (for example, the K^{th} row) and the second signal pin (in the seventh column) in the eighth row (for example, the M^{th} row) are disposed in a staggered manner with respect to the blank region 50. Because the two are disposed in a staggered manner, a larger pitch of wiring may be used during wiring, thereby preventing wires from being too close to cause signal crosstalk. Certainly, the first signal pin 31 (in the second column) in the fourth row (for example, the Lth row) and the second signal pin 41 (in the second column) in the ninth row (for example, the N^{th} row) are disposed opposite to each other. It should be noted that M, N, K, and L are all positive integers greater than or equal to 1.

As shown in FIG. 6, the first signal pin 31 and the second signal pin 41 belong to the first signal channel 14 (shown in FIG. 1). Therefore, the first signal channel 14 may include 16 signal pins, for example, 16 signal pins are total from DQ0_A to DQ15_A, where A represents the first signal channel. In this embodiment of the present disclosure, DQ0_A to DQ7_A include eight signal pins in total, which are configured to transmit low-order data byte signals (byte0). DQ8_A to DQ15_A include eight signal pins in total, which are configured to transmit high-order data byte signals (byte1). When the package substrate 20 is installed on a circuit board, a signal of the package substrate 20 needs to match a signal of a control die (CPU). In addition, signal pins on the CPU are fixed, and to prevent metal wires from being crossed on the circuit board, the first signal pins 31 are configured to transmit higher-order data byte signals, and the second signal pins 41 are configured to transmit lower-order data byte signals, so that the package structure 20 can better match the CPU, ensuring normal signal transmission. In some embodiments, the first signal pins 31 may alternatively be configured to transmit low-order data byte signals, and the second signal pin 41 may alternatively be configured to transmit high-order data byte signals.

As shown in FIG. 6, the third pin array 60 is disposed on a right upper part of the base 21. In the row direction, the third pin array 60 includes five columns of pins, and in the column direction, the third pin array 60 includes seven rows of pins. Therefore, the third pin array may include 35 pins. In this embodiment, the pin in the fifth row and the thirteenth column is removed, which facilitates subsequent control of wiring for the pins. In this case, the third pin array 60 includes 34 pins. A plurality of control pins are disposed in the third pin array 60, and the control pins include, for example, a command/address (CA) pin 61 and a chip select (CS) signal pin 62. The command/address pin 61 may receive a read address or a write address. The read address includes a row and a column of a memory array for reading, and the write address includes a row and a column of the memory array for writing. The chip select signal pin 62 is configured to transmit a chip select signal, and the memory controller selects a corresponding die (die) with the chip select signal, so as to perform independent data, address, or command transmission for the selected die.

As shown in FIG. 6, the third pin array 60 includes seven command/address pins 61, for example, CA0_A to CA6_A, where A represents the first signal channel. In the row direction, two command/address pins 61 may be disposed adjacent to each other, that is, two command/address pins 61 may be disposed contiguously. Because the command/address pins 61 are configured to transmit control signals, and a frequency of the control signals is relatively low, the two command/address pins 61 may be disposed adjacent to each other. To prevent crosstalk between control signals, at most two command/address pins 61 are disposed adjacent to each other in the row direction, and in the vertical direction, the command/address pins 61 are disposed at intervals, to avoid a case in which four command/address pins 61 are disposed adjacent to each other, causing relatively large signal crosstalk. In the column direction, at least one command/address pin 61 is adjacent to the blank region 50, which facilitates wiring for the command/address pin 61. In some embodiments, if pins in the eighth row of the first pin array 30 are removed, two command/address pins 61 in the third pin array 60 are adjacent to the blank region 50, thereby facilitating wiring for the command/address pins 61.

As shown in FIG. 6, the third pin array 60 includes two chip select signal pins 62, for example, CS1_A and CS0_A. CS0_A represents a first die (Chip0) under the first signal channel, and CS1_A represents a second die (Chip1) under the first signal channel. In the row direction, the two chip select signal pins 62 are disposed adjacent to each other. One chip select signal pin 62 may be adjacent to the blank region 50, thereby facilitating wiring for the chip select signal pin 62. In this embodiment, to facilitate wiring for the chip select signal pin 62, a distance between the chip select signal pin 62 and the command/address pin 61 is relatively far. In some embodiments, the chip select signal pin 62 may alternatively be disposed adjacent to the command/address pin 61, so that a better timing match is formed between a chip select signal and a command/address signal.

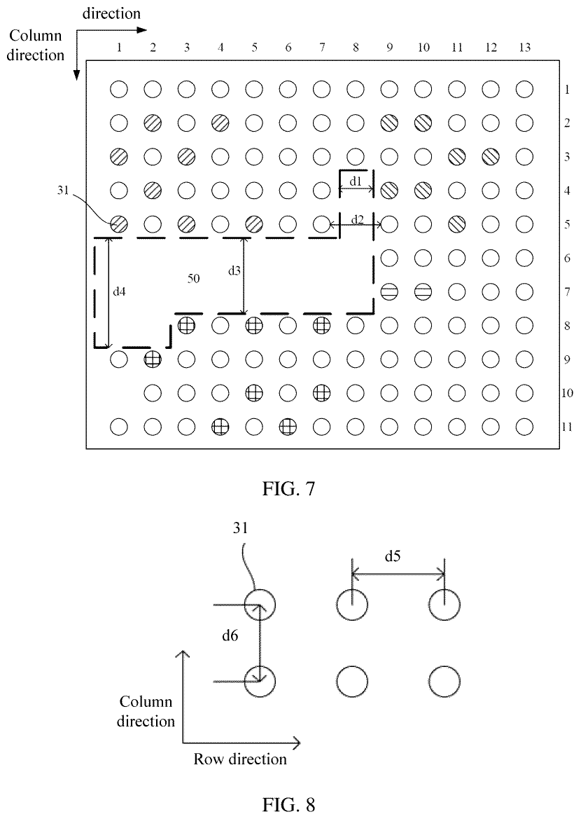

As shown in FIG. 7, in this embodiment, some pins are removed to form the blank region 50, and positions of the first signal pins 31 are rearranged, so that more first signal pins 31 are adjacent to the blank region 50, improving a wiring manner for the first signal pins 31. Because there is a gap between pins, after some pins are removed, a minimum dimension of the blank region 50 is greater than the diameter of the pin. For example, as shown in FIG. 7, in the row direction, the pin in the eighth column and the fourth row is removed. In this case, a minimum dimension d1 of the blank region 50 is greater than the diameter of the pin. In this case, the blank region 50 has a large area, and a large wiring area is formed on the PCB, which facilitates wiring for the pins. Certainly, in the row direction, the pin in the eighth column and the fifth row is removed. In this case, a pitch d2 between the pin in the fifth row and the seventh column and the pin in the fifth row and the ninth column may be defined as a minimum dimension of the blank region 50, and the pitch d2 is also greater than the diameter of the pin. In the column direction, pins in the sixth to seventh rows and the third to seventh columns are removed. In this case, a pitch between the pin in the fifth row and the fourth column and the pin in the eighth row and the fourth column is d3. The pitch d3 is greater than the pitch d2, and likewise, the pitch d4 is greater than the pitch d3. In this embodiment of the present disclosure, the blank region 50 extends from the center of the base 21 to the edge. For example, in the row direction, the blank region 50 extends from the first column to the eighth column, and an end part of the blank region 50 extends to the edge. In other words, in the row direction, the length of the blank region 50 is greater than the length of the first pin array 30. Therefore, during wiring, the blank region 50 forms a corresponding blank area on the PCB, and the length of the blank area is greater than the length of the first pin array 30. In this case, during wiring in the blank area, there is no pin for blocking, so that wiring can be performed on a surface of the PCB instead of being performed inside the PCB. Therefore, a wiring process is simplified.

As shown in FIG. 7 and FIG. 8, in the row direction, the width of the blank region 50 is gradually reduced, for example, from the pitch d4 to the pitch d3 to the pitch d2 or d1. During wiring, a shape of the blank area on the PCB is the same as that of the blank region 50. A large quantity of wires need to extend from an edge of the blank area to the blank area, and then are connected to the pins. Therefore, an end part of the blank region 50 is wide, and the width of the blank area on the PCB is wide, so that a pitch between wires at the edge of the blank area is proper, which facilitates the wiring process and reduces signal crosstalk. In the row direction, a pitch between adjacent pins (for example, first signal pins 31) is d5. In the column direction, a pitch between adjacent pins (for example, first signal pin 31) is d6. In the row direction, the minimum dimension d1 or d2 of the blank region 50 is greater than the pitch d5. In the column direction, the pitch d3 or d4 of the blank region 50 is greater than the pitch d6. Therefore, a pitch between adjacent pins cannot be defined as a blank region. That is, in this embodiment, the minimum dimension of the blank region 50 is greater than the pitch between adjacent pins, and the minimum dimension of the blank region 50 may also be greater than the diameter of the pin. In this embodiment of the present disclosure, the diameter of the pin is, for example, 350 microns; the pitch d5 is, for example, 600 microns; and the pitch d6 is, for example, 500 microns. Due to the existence of the blank region 50, a quantity of pins on the base 21 is reduced, and therefore, a pitch between pins can be reduced, and a size of the base 21 can be reduced. In addition, because the pitch between pins is reduced, the length of the wire is reduced, and a signal loss is reduced.

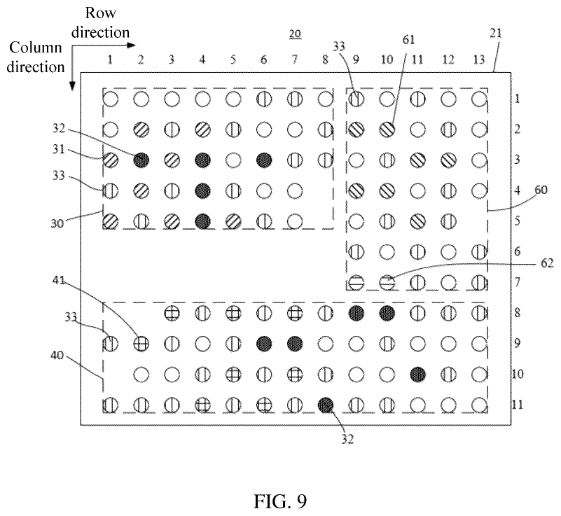

As shown in FIG. 9, in some embodiments of the present disclosure, power pins are disposed in both the first pin array 30 and the second pin array 40. First power pins 32 and second power pins 33 are disposed in both the first pin array 30 and the second pin array 40. The first power pin 32 is disposed adjacent to the first signal pin 31, and the second power pin 33 may also be disposed adjacent to the first signal pin 31. For example, in the fifth row (the K^{th} row), pins in the first column to the sixth column are respectively a first signal pin 31, a second power pin 33, a first signal pin 31, a first power pin 32, a first signal pin 31, and a second power pin 33 in the row direction. The first power pin 32 transfers, for example, a first voltage, the second power pin 33 transfers, for example, a second voltage, and the first voltage may be greater than the second voltage. The first voltage is, for example, 0.5 V, and the second voltage is, for example, a ground voltage (0 V). The first power pin 32 may be distributed between first signal pins 31, and the second power pin 33 may be distributed between first signal pins 31. Because voltages of both the first power pin 32 and the second power pin 33 are relatively low, a magnetic field generated by the first signal pins 31 may be absorbed, thereby reducing crosstalk between first signal pins 31. Similarly, in the second pin array 40, the first power pin 32 and the second power pin 33 are also distributed between second signal pins 41, and the first power pin 32 and the second power pin 33 may also absorb a magnetic field generated by the second signal pins, thereby reducing crosstalk between the second signal pins 41.

As shown in FIG. 9, in this embodiment of the present disclosure, the first power pins 32 may be contiguously arranged. In the first pin array 30, three first power pins 32 are contiguously arranged in the fourth column. In this application, positions of the first signal pins 31 are first designed, and then the first power pin 32 and the second power pin 33 are disposed between first signal pins 31. In this way, the first power pin 32 and the second power pin 33 may be distributed between the first signal pins 31. In addition, because the first power pins 32 are relatively close to an edge of the base 21, and the first power pins 32 are connected to each other, three first power pins 32 are contiguously arranged, thereby increasing stability of power supply. If more (four or more) first power pins 32 are contiguously arranged, the size of the first pin array 30 is increased, resulting in an increase in the area of the base 21, which is not conducive to miniaturization of the base 21. Therefore, in the column direction, at most three first power pins 32 may be disposed adjacent to each other in the first pin array 30. Certainly, in the row direction, at most three first power pins 32 may be disposed adjacent to each other in the first pin array 30. Certainly, the first power pins 32 may alternatively be separated in the first pin array 30, that is, the first power pins 32 are disposed at intervals of each other.

As shown in FIG. 9, in the second pin array 40, a first power pin 32 and a second power pin 33 may be distributed between second signal pins 41, thereby reducing crosstalk between the second signal pins 41. In addition, in the eighth row (the M^{th} row), pins in the third column to the eighth column are a first signal pin 41, a second power pin 33, a first signal pin 41, a second power pin 33, a second signal pin 41, and a second power pin 33. Because the second power pin 33 transmits a ground voltage, a magnetic field of the second signal pins 41 can be better absorbed, thereby further reducing crosstalk between the second signal pins 41. In addition, the second pin array 40 is located in a lower part of the base 21, and the first voltage is transmitted from an upper part of the base 21 to a lower part, that is, is transmitted in the column direction. Therefore, the first voltage in the second pin array 40 is relatively stable. Two first power pins 32 may be contiguously arranged in the second pin array 40, and there is no need to contiguously arrange three or more first power pins 32.

As shown in FIG. 9, in the fifth row, a first power pin 32 is disposed between first signal pins 31. In the eighth row, a second power pin 33 is disposed between second signal pins 41. The fifth row is closer to the upper part of the base 21, and the eighth row is located in the lower part of the base 21. Therefore, to ensure stability of the first voltage, three first power pins 32 that are contiguously arranged in the first pin array 30 are configured in this embodiment of the present disclosure, so as to ensure stability of the first voltage. Therefore, in the fifth row, the first power pin 32 may isolate the first signal pins 31. In the second pin array 40, the first voltage is relatively stable. To further reduce crosstalk of the second signal pins 41, in the eighth row, the second power pin 33 may isolate the second signal pins 41. In addition, the second power pin 33 is further located in the third pin array 60, and the second power pin 33 is adjacent to the command/address pin 61 and the chip select signal pin 62, thereby reducing crosstalk between these signals.

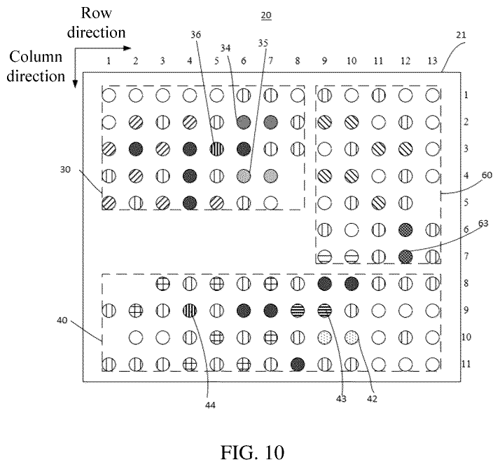

As shown in FIG. 10, a first read strobe pin 34 and a first write clock pin 35 are further disposed in the first pin array 30. The first read strobe pin 34 may be associated with a first signal pin 31, and the first write clock pin 35 may be associated with a first signal pin 31. The first read strobe pin 34 and the first signal pin 31 are disposed at an interval, and are separated from each other by the second power pin 33, thereby reducing signal crosstalk between the two. The first write clock pin 35 and the first signal pin 31 are adjacent in a diagonal direction, that is, the two are not adjacent in the row direction and the column direction. Therefore, a pitch between the first signal pin 31 and the first write clock pin 35 is relatively large, and magnetic field coupling generated by the two is reduced, thereby reducing signal crosstalk. In addition, the first read strobe pins 34 and the first write clock pins 35 are separated by the first power pin 32 and the second power pin 33, that is, the first power pin 32 and the second power pin 33 are disposed between the first read strobe pins 34 and the first write clock pins 35. Therefore, the first power pin 32 and the second power pin 33 may absorb a magnetic field generated by each of the first read strobe pins 34 and the first write clock pins 35, thereby reducing signal crosstalk between the first read strobe pins 34 and the first write clock pins 35. The first write clock pin 35 is further adjacent to the blank region 50. Therefore, a wire of the first write clock pin 35 may be led out of the blank region 50, thereby facilitating a wiring process.

As shown in FIG. 10, second read strobe pins 42 and second write clock pins 43 are disposed in the second pin array 40. A second power pin 33 is disposed between the second read strobe pin 42 and the second signal pin 41, so as to reduce signal crosstalk. In addition, the second write clock pin 43 and the second signal pin 41 are disposed on a diagonal line, which can also reduce signal crosstalk. The second read strobe pins 42 and the second write clock pins 43 are staggered. For example, the second read strobe pins 42 are located in the ninth to tenth columns, and the second write clock pins 43 are located in the eighth to ninth columns. In addition, the second read strobe pins 42 and the second write clock pins 43 are surrounded by first power pins 32 and second power pins 33, so that the second read strobe pin 42 is adjacent to the first power pin 32, the second write clock pin 43 is adjacent to the second power pin 33, and magnetic fields generated by the second read strobe pin 42 and the second write clock pin 43 are absorbed by the first power pin 32 and the second power pin 33, thereby reducing signal crosstalk between the second read strobe pin 42 and the second write clock pin 43.

As shown in FIG. 10, the first read strobe pin 34 is configured to transmit a first read strobe signal, and the first write clock pin 35 is configured to transmit a first data clock signal. The second read strobe pin 42 is configured to transmit a second read strobe signal, and the second write clock signal is used to transmit a second data clock signal. The first read strobe signal and the first data clock signal may be associated with higher-order data byte signals (DQ8 to DQ15). The second read strobe signal and the second data clock signal may be associated with low-order data byte signals (DQ0 to DQ7). The first read strobe signal and the second read strobe signal may be differential signals (a pair of a true signal and a complement signal). The first read strobe pin 34 is, for example, represented by RDQS1_C_A and RDQS1_T_A, and A represents the first signal channel. The second read strobe pin 42 is, for example, represented by RDQS0_C_A and RDQS0_T_A. The first write clock pin 35 is, for example, represented by WCK1_C_A and WCK1_T_A, and the second write clock pin 43 is, for example, represented by WCK0_C_A and WCK0_T_A.

As shown in FIG. 9 and FIG. 10, the eighth column of the first pin array 30 is adjacent to the third pin array 60, and a second power pin 33 is disposed in the eighth column. The first read strobe pin 34 is isolated from the command/address pin 61 by the second power pin 33, and the second power pin 33 is adjacent to the command/address pin 61, thereby reducing crosstalk between signals of the two. Due to the existence of the blank region 50, the first write clock pin 35 is separated from the command/address pin 61, that is, the first write clock pin 35 and the command/address pin 61 are located on opposite sides of the blank region 50, thereby reducing signal crosstalk between the two with the blank region 50. The eighth row of the second pin array 40 is adjacent to the third pin array 60, and the second write clock pin 42 is separated from the chip select signal pin 62 by the first power pin 32, thereby reducing signal crosstalk between the two. In addition, stability of the first voltage in the second pin array 40 may be ensured with the first power pin 32.

As shown in FIG. 10, control signals in the third pin array 60 further include clock signal pins 63, and the clock signal pins 63 are associated with the command/address pins 61. The clock signal pins 63 may be differential signals, for example, represented by CK_C_A and CK_T_A.

As shown in FIG. 9 and FIG. 10, a first data mask flip pin 36 is further disposed in the first pin array 30. The first data mask flip pin 36 is configured to transmit a first data mask flip signal associated with a higher-order data byte signal. The first data mask flip pin 36 is surrounded by the first power pins 32 and the second power pins 33, so as to absorb a magnetic field generated by the first data mask flip pin 36, and reduce signal crosstalk between the first data mask flip pin 36 and the first signal pin 31. The first data mask flip pin 36 may be represented by DMI1_A. The first signal pin 31, the first read strobe pin 34, the first write clock pin 35, the first data mask flip pin 36, the command/address pin 61, the chip select signal pin 62, and the clock signal pin 63 are all coupled to the first signal channel. A second data mask flip pin 44 is further disposed in the second pin array 40. The second data mask flip pin 44 is configured to transmit a second data mask flip signal associated with a low-order data byte signal. The second data mask flip pin 44 is surrounded by the second power pins 33, so as to absorb a magnetic field generated by the second data mask flip pin 44 and reduce signal crosstalk between the second data mask flip pin 44 and the second signal pin 41. The second data mask flip pin 44 may be represented by DMI0_A. The second signal pin 41, the second read strobe pin 42, the second write clock pin 43, and the second data mask flip pin 44, the command/address pin 61, the chip select signal pin 62, and the clock signal pin 63 are all coupled to the first signal channel, that is, the first pin array 30, the second pin array 40, and the third pin array 60 may be configured to transmit signals for the first signal channel.

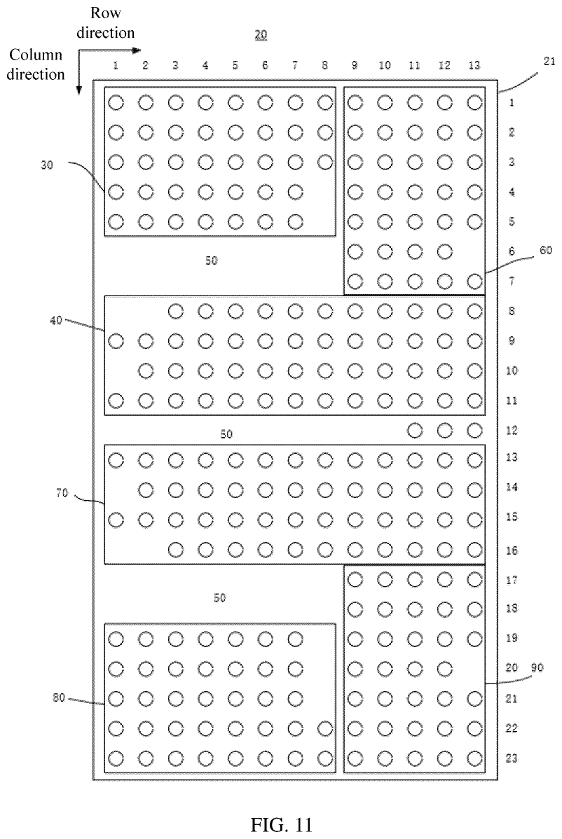

As shown in FIG. 10 and FIG. 11, FIG. 10 is a schematic diagram of some pin arrays, and FIG. 11 is a schematic diagram of all pin arrays. FIG. 10 shows the first pin array 30, the second pin array 40, and the third pin array 60. A fourth pin array 70, a fifth pin array 80, and a sixth pin array 90 are further disposed on the base 21. The first pin array 30 and the fifth pin array 80 are substantially mirror images with respect to a center row (the twelfth row) of the base 21. The second pin array 40 and the fourth pin array 70 are substantially mirror images with respect to the center row of the base 21. The third pin array 60 and the sixth pin array 90 are substantially mirror images with respect to the center row of the base 21. In addition, the blank region 50 is disposed between the first pin array 30 and the second pin array 40. A blank region 50 is disposed between the second pin array 40 and the fourth pin array 70, and a blank region 50 is disposed between the fifth pin array 80 and the fourth pin array 70. Pins are not disposed in the three blank regions 50, thereby facilitating a subsequent wiring process. The fourth pin array 70, the fifth pin array 80, and the sixth pin array 90 may be configured to transmit signals for the second signal channel.

It should be noted that the pins of the first pin array 30 and pins of the fifth pin array 80 are substantially mirror images. Therefore, positions of signal pins in the first pin array 30 and positions of signal pins in the fifth pin array 80 are mirror images. In some embodiments, to facilitate subsequent wiring processes, the positions of the signal pins in the first pin array 30 and the positions of the signal pins in the fifth pin array 80 may not be mirror images.

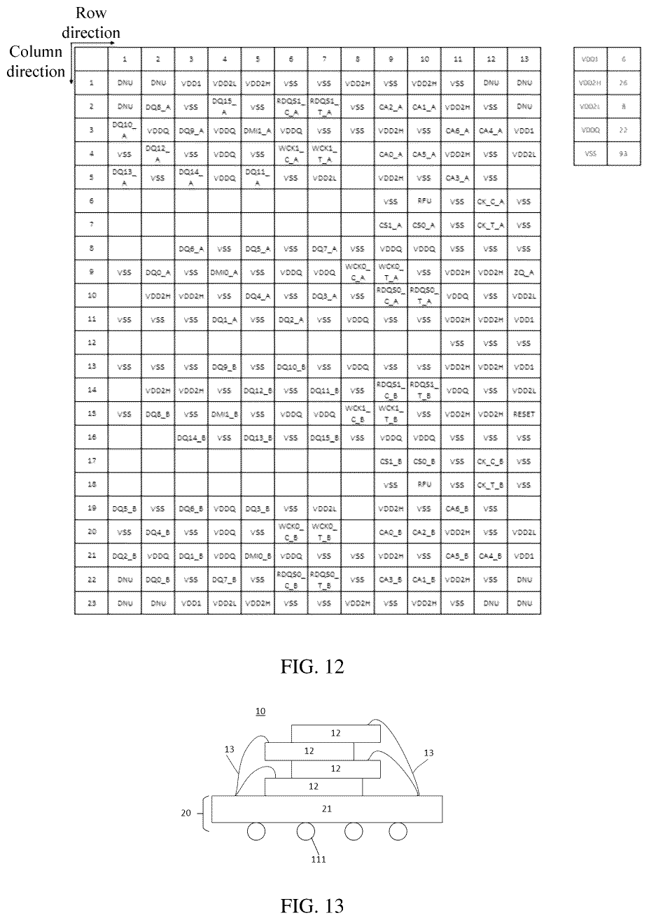

As shown in FIG. 11 and FIG. 12, FIG. 12 is a schematic diagram of a pin architecture. In this embodiment of the present disclosure, there are 13 rows and 23 columns of pins on the substrate. Due to the existence of the blank region 50, a quantity of pins is reduced, and therefore, a pitch between pins may be reduced. In this embodiment of the present disclosure, the quantity of pins is, for example, 245. The power pins may include a VDD1 pin, a VDD2H pin, a VDD2L pin, and a VDDQ pin. The VDD1 pin receives VDD1 and supplies power to a memory core. The VDD2H pin receives VDD2H and supplies power to the memory core. The VDD2L pin receives VDD2L and also supplies power to the memory core. The VDDQ pin receives VDDQ and supplies power to an I/O buffer. In actual application, there may be three groups of voltages in the memory, which are respectively VDD1, VDD2, and VDDQ. VDD2 may include VDD2H and VDD2L. VDD1 and VDD2 indicate working voltages of the memory core, VDD1 (1.8V) and VDD2 have different voltage values, VDD2H indicates a relatively high voltage value (1.05V), VDD2L (0.9V) indicates a relatively low voltage value, and VDDQ (0.5v) indicates a high-quality voltage that has undergone noise filtering, and has high anti-interference strength. The VSS pin indicates a ground pin. There are six VDD1 pins, 26 VDD2H pins, eight VDD2L pins, 22 VDDQ pins, and 93 VSS pins.

As shown in FIG. 12, pins CA0 to CA6 may receive read addresses or write addresses. The read address includes a row and a column of the memory array on which reading is to be performed, and the write address includes a row and a column of the memory array on which writing is to be performed. Write data may be received and read data may be output by the pins DQ0 to DQ15. During a read operation, data read from the memory cell is output by the pins DQ0 to DQ15. During a write operation, data to be written into the memory cell is received by the pins DQ0 to DQ15.

As shown in FIG. 12, WCK1_T, WCK1_C, WCK0_T, and WCK0_C represent write clocks, and the write clocks are configured to sample write data received by DQ0 to DQ15. In actual application, WCK1_T and WCK1_C are configured to sample write data received by pins DQ8 to DQ15, and WCK0_T and WCK0_C are configured to sample write data received by pins DQ0 to DQ7. WCK1_T, WCK1_C, WCK0_T, and WCK0_C may run at twice or four times a frequency of CK_T/CK_C to increase a sampling rate. RDQS1_T, RDQS1_C, RDQS0_T, and RDQS0_C represent read clocks, and are also referred to as read strobe signals. The read clocks are configured to sample the read data output by DQ0 to DQ15.In actual application, RDQS1_T and RDQS1_C are configured to sample read data output by the pins DQ8 to DQ15, and RDQS0_T and RDQS0_C are configured to sample read data output by the pins DQ0 to DQ7. DMI1 and DMI0 represent data mask (DM) signals, and the data mask signals are used to mask the write data received by the pins DQ0 to DQ15, to determine write data that is to be written into the memory cell. In actual application, DMI1 is used to mask the write data received by the pins DQ8 to DQ15, and DMI0 is used to mask the write data received by the pins DQ0 to DQ7. CK_T and CK_C represent command address clocks, and the command address clocks are configured to sample the read address or the write address. In actual application, all commands, addresses, and input control signals are sampled at an intersection of a rising edge of CK_T and a falling edge of CK_C. ZQ is received by the ZQ pin. ZQ represents a calibration signal, and the calibration signal is configured to calibrate output drive strength. RESET is received by a RESET pin. RESET represents a reset signal, and the reset signal is used to reset the memory to a default state during initialization. CS is received by a CS pin. CS represents a chip select signal, and the chip select signal is used to select a target die. A DNU pin represents a mechanical ball, which has no function. An RFU pin is a reserved pin. In FIG. 12, A may represent the first signal channel, and B may represent the second signal channel. Certainly, A may represent the second signal channel, and B may represent the first signal channel.

As shown in FIG. 12, in some embodiments, the quantity and positions of power pins (for example, VSS pins) may be appropriately changed, for example, the quantity of power pins may be appropriately increased or decreased, so that the quantity of pins may be changed between 234 and 250, for example, 235, 236, 237, 238, 239, 241, 242, 243, 244, 245, 246, 247, 248, or 249 pins. It should be noted that the positions and quantities of signal pins (e.g., DQ pins) and control pins (e.g., CA pins) do not change.

As shown in FIG. 13, an embodiment of the present disclosure further proposes another semiconductor structure 10. The semiconductor structure 10 includes a package structure 20 and memory dies 12. The package structure 20 includes a base 21 and pins 111 located on a back side of the base 21, that is, the package structure 20 may be a package substrate. For a structure of the package structure 20, refer to the foregoing description. For an arrangement manner of the pins 111, refer to the foregoing description. The memory die 12 is located on the base 21, and the memory die 12 is electrically connected to a pad (shown in FIG. 2) of the base 21 through a gold wire 13. There is an internal wire (metal wire) in the base 21, so that the pin 111 is electrically connected to the pad, so as to be electrically connected to the gold wire 13. In this embodiment of the present disclosure, a first signal channel 14 is electrically connected to two memory dies 12, and a second signal channel 15 is electrically connected to two memory dies 12.

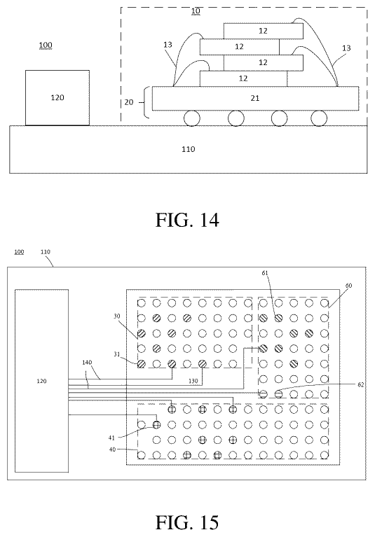

As shown in FIG. 14, an embodiment of the present disclosure further proposes an electronic device 100. The electronic device 100 may include a circuit board 110, a first die 120, and a semiconductor structure 10. The first die 120 may be a control die. For a structure of the semiconductor structure 10, refer to the foregoing description. A memory die 12 in the semiconductor structure 10 may be a second die. The first die 120 may control an overall operation of the memory die 12. For example, the first die 120 may control the memory die 12, so that data is output from the memory die 12 or data is stored in the memory die 12. The first die 120 may be a SOC die. The memory die 12 may include a plurality of memory units. For example, the memory unit may be a dynamic random access memory (DRAM) unit. The memory die 12 may be a double data rate (DDR), a low power double data rate (LPDDR), a graphic double data rate (GDDR), a wide I/O, or a high bandwidth memory (HBM). In this embodiment, the memory die 12 is, for example, LPDDR5.

As shown in FIG. 14 and FIG. 15, FIG. 15 is a top view of FIG. 14 on the circuit board 110. It should be noted that in FIG. 15, only the first pin array 30, the second pin array 40, and the third pin array 60 are displayed, that is, pins under the first signal channel are displayed. Because the semiconductor structure 10 is secured to the circuit board 110 through pins, the pins in the first pin array 30, the second pin array 40, and the third pin array 60 may be displayed on the circuit board 110. In addition, a blank area 130 is further formed between the first pin array 30 and the second pin array 40, and the shape of the blank area 130 is the same as the shape of the blank region 50 in the package structure 10. That is, the blank region 50 in the package structure 10 correspondingly forms the blank area 130 on the circuit board 110. For structure description of the blank area 130, refer to the structure description of the blank region 50. In addition, a metal wire 140 (metal wiring) is disposed on a surface of the circuit board 110, and the metal wire 140 is interconnected to the first die 120 through the blank area 130, so that the first die 120 and the memory die 12 implement signal transmission. Because the blank area 130 is designed, that is, no pin is disposed in the blank area 130, the metal wire 140 may be directly designed in the blank area 130, and the length of the metal wire 140 is relatively short, and a signal loss is small. If some pins are reserved in the blank area 130, when the metal wire 140 is being designed in the blank area 130, the pins need to be avoided, which causes the length of the metal wire 140 to become longer and the signal loss to increase. In addition, if the metal wire 140 is designed inside the circuit board 110, a wiring process is relatively complex.

As shown in FIG. 15, the electronic device 100 may include one or more of the following: e.g., a smart phone, a tablet personal computer (PC), a mobile phone, a video phone, an e-book (e-book) reader, a desktop PC, a laptop PC, a netbook computer, a workstation, a server, a personal digital assistant (PDA), a portable multimedia player (PMP), an MPEG-1 audio layer 3 (MP3) player, a mobile medical device, a camera, a home appliance, a medical device, an Internet of Things (IoT) device, and a wearable device. The wearable device may be of an accessory type, a fabric or clothing type, a body attachment type, or an implantable circuit type. An accessory-type wearable device may be, e.g., a watch, a ring, a bracelet, an anklet, a necklace, glasses, contact lenses, or a head-mounted device (HMD).

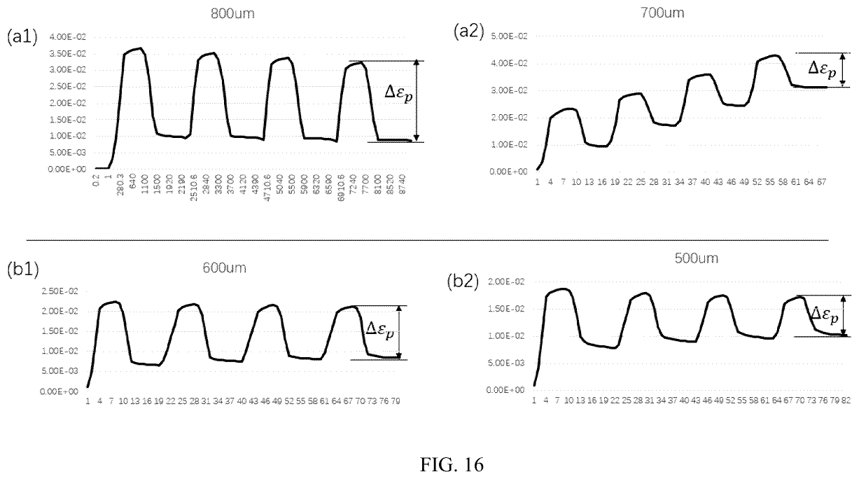

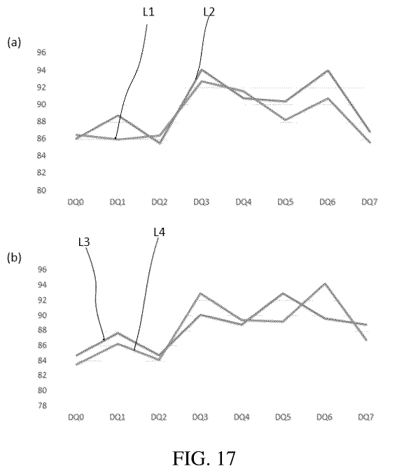

As shown in FIG. 16, FIG. 16 is a diagram of plastic strain comparison between a package substrate in some implementations and the package substrate in embodiments of the present disclosure. In FIG. 16, a horizontal coordinate indicates a quantity of temperature cycles, and a vertical coordinate indicates the strain. It should be noted that the package substrate in some implementations has 315 pins, and the package substrate in the embodiments has 245 pins. In the diagram (a1), 800 μm indicates a pitch of the package substrate in some implementations in the X direction (row direction), and in the diagram (a2), 700 μm indicates a pin pitch of the package substrate in some implementations in the Y direction (column direction). In the diagram (b1), 600 μm indicates a pitch of the package substrate in the embodiments in the X direction (row direction), and in the diagram (b2), 500 μm indicates a pin pitch of the package substrate in the embodiments in the Y direction (column direction). In the X direction, the comparison shows that the strain curve in the diagram (a1) is stable only after a large quantity of temperature cycles (more than 8000 times), and the final strain differenceΔϵₚ is 0.0236. However, the strain curve in the diagram (b1) is stable after dozens of temperature cycles, and the final strain differenceΔϵₚ is 0.0128. Therefore, in the X direction, a strain of a pin of the package substrate in some implementations is greater than a strain of a pin of the package substrate in the embodiments. In the Y direction, the strain curve in the diagram (a2) becomes stable only after hundreds of temperature cycles, and the final strain differenceΔϵₚ is 0.0185. However, the strain curve in the diagram (b2) becomes stable after dozens of temperature cycles, and the final strain differenceΔϵₚ is 0.00711. Therefore, in the Y direction, a strain of a pin of the package substrate in some implementations is greater than a strain of a pin of the package substrate in the embodiments. In addition, the pins of the package substrate in some implementations have a large difference in strain in the X/Y directions, and the deformation of the pins in the X/Y directions is inconsistent, which is not conducive to subsequent welding. However, the pins of the package substrate in the embodiments of the present disclosure have a small difference in strain in the X/Y directions, and the deformation of the pins in the X/Y directions is basically consistent, which is conducive to subsequent welding. In this embodiment, the quantity of pins is reduced, a blank region is designed, a pin pitch is reduced, an overall size of the package substrate is also reduced, a stress expansion point of the pin is also reduced, the pin has good plastic application performance, and a stress of the pin is relatively small, thereby improving pin reliability.

As shown in FIG. 17, FIG. 17 shows a diagram of performance testing on the package substrate in some implementations and the package substrate in the embodiments. In the diagram (a), the curve L1 represents a test graph of written data of the package substrate (with 315 pins) in some implementations, and the curve L2 represents a test graph of written data of the package substrate (with 245 pins) in the present disclosure. The curve L1 and the curve L2 represent test graphs of the two substrates at the same eye width and the same writing rate (the writing rate is, for example, 7500 Mbps). It can be learned from the diagram (a) that a variation curve of the curve L1 and a variation curve of the curve L2 are basically the same, and test performance of the package substrate in the present disclosure may be basically the same as write performance of the package substrate in some implementations. In the diagram (b), the curve L3 represents a test graph of read data of the package substrate in the embodiments, and the curve LA represents a test graph of read data of the package substrate in some implementations. The curve L3 and the curve L4 represent test graphs of the two substrates at the same eye width and the same reading rate (the reading rate is, for example, 7500 Mbps). It can be learned from the diagram (a) that a variation curve of the curve L3 and a variation curve of the curve L4 are basically the same, and test performance of the package substrate in the present disclosure may be basically the same as read performance of the package substrate in some implementations. It can be learned from the foregoing tests that, in the present disclosure, the quantity of pins is reduced, and positions of signal pins, control pins, and power pins are rearranged, so that the performance of the package substrate can be consistent with the performance of the package substrate in some implementations, and the package substrate in the embodiments can be applied to a miniaturized electronic product.

In conclusion, embodiments of the present disclosure propose a package structure, a semiconductor structure, and an electronic device. The package structure includes a base, a first pin array, and a second pin array. A blank region is disposed between the first pin array and the second pin array, that is, no pin is disposed between the first pin array and the second pin array. In this way, the first pin array and the second pin array are separated. Therefore, a quantity of pins on the base is reduced, and a pin pitch can be reduced, so that an area of the substrate can be reduced, and an area of the package structure can be further reduced, so that the package structure can be applied to a miniaturized electronic product.

In addition, a first data pin in the first pin array and/or a second data pin in the second pin array are/is adjacent to the blank region. Therefore, when the package structure is applied to a circuit board, the blank region on the base correspondingly forms a blank area on the circuit board. Therefore, the first data pin and/or the second data pin are also adjacent to the blank area on the circuit board. In this way, a metal wire may be directly formed on a surface of the circuit board. The metal wire is electrically connected to the package structure and a control die, and therefore, a metal wire does not need to be formed inside the circuit board.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A package structure, comprising:
a base;
a first pin array, disposed on the base, wherein the first pin array comprises a plurality of first data pins; and
a second pin array, disposed on the base, wherein the second pin array comprises a plurality of second data pins;
wherein a blank region is disposed between the first pin array and the second pin array, the blank region extends from a center of the base to an edge of the base, an end part of the blank region is located outside the first pin array, at least one first data pin is adjacent to the blank region, and a minimum dimension of the blank region is greater than a diameter of the first data pin.

2. The package structure according to claim 1, wherein in the first pin array, a quantity of first data pins in the K^{th} row is greater than a quantity of first data pins in the Lth row;
wherein the K^{th} row is adjacent to the blank region, and the Lth row is adjacent to the K^{th} row.

3. The package structure according to claim 2, wherein in the second pin array, a quantity of second data pins in the M^{th} row is greater than a quantity of second data pins in the N^{th} row;
wherein the M^{th} row is adjacent to the blank region, and the N^{th} row is adjacent to the M^{th} row.

4. The package structure according to claim 3, wherein the first data pin in the K^{th} row and the second data pin in the M^{th} row are disposed opposite to each other or are staggered, and the first data pin in the Lth row and the second data pin in the N^{th} row are disposed opposite to each other.

5. The package structure according to claim 3, wherein in the N^{th} row, at least one second data pin is adjacent to the blank region.

6. The package structure according to claim 3, wherein in the K^{th} row, a first power pin is disposed between adjacent first data pins; and in the M^{th} row, a second power pin is disposed between adjacent second data pins;
wherein the first power pin is configured to transmit a first voltage, the second power pin is configured to transmit a second voltage, and the first voltage is higher than the second voltage.

7. The package structure according to claim 6, wherein at most three first power pins in the first pin array are disposed adjacent to each other in a column direction; and at most two first power pins in the second pin array are disposed adjacent to each other in a row direction.

8. The package structure according to claim 1, wherein the first data pin is configured to transmit a high-order data byte signal, and the second data pin is configured to transmit a low-order data byte signal; or the first data pin is configured to transmit a low-order data byte signal, and the second data pin is configured to transmit a high-order data byte signal.

9. The package structure according to claim 6, wherein the first pin array further comprises:
first read strobe pins, disposed at an interval from the first data pin; and
first write clock pins, disposed at an interval from the first data pin;
wherein the first power pin and the second power pin are disposed between the first read strobe pins and the first write clock pins.

10. The package structure according to claim 9, wherein the first write clock pin is adjacent to the blank region.

11. The package structure according to claim 6, wherein the second pin array further comprises:
second read strobe pins, disposed at an interval from the second data pin; and
second write clock pins, disposed at an interval from the second data pin;
wherein the second read strobe pins and the second write clock pins are staggered, and at least one of the second read strobe pins is adjacent to at least one of the second write clock pins.

12. The package structure according to claim 11, wherein the second read strobe pin is adjacent to the first power pin, and the second write clock pin is adjacent to the second power pin.

13. The package structure according to claim 6, wherein the base is provided with:
a third pin array, comprising a plurality of control pins;
wherein at least one of the control pins is adjacent to the blank region.

14. The package structure according to claim 13, wherein the control pins comprise a plurality of command/address pins, wherein at most two of the command/address pins are disposed adjacent to each other; and at least one of the command/address pins is adjacent to the blank region.

15. The package structure according to claim 14, wherein the second power pin in the first pin array is adjacent to the command/address pin in the third pin array; and the first power pin in the second pin array is adjacent to the control pin in the third pin array.

16. The package structure according to claim 14, wherein the command/address pin and the first write clock pin are located on opposite sides of the blank region.

17. A package structure, comprising:
a base;
a first pin array, disposed on the base, wherein the first pin array comprises a plurality of first data pins; and
a second pin array, disposed on the base, wherein the second pin array comprises a plurality of second data pins;
wherein a blank region is disposed between the first pin array and the second pin array, the blank region extends from a center of the base to an edge of the base, an end part of the blank region is located outside the first pin array, at least one second data pin is adjacent to the blank region, and a minimum dimension of the blank region is greater than a diameter of the first data pin.

18. A package structure, comprising:
a base;
a first pin array, disposed on the base, wherein the first pin array comprises a plurality of first data pins; and
a second pin array, disposed on the base, wherein the second pin array comprises a plurality of second data pins;
wherein a blank region is disposed between the first pin array and the second pin array, the blank region extends from a center of the base to an edge of the base, an end part of the blank region is located outside the first pin array, at least one first data pin is adjacent to the blank region and at least one second data pin is adjacent to the blank region, and a minimum dimension of the blank region is greater than a diameter of the first data pin.

19. A semiconductor structure, comprising the package structure according to claim 1 and a die disposed on the package structure.

20. An electronic device, comprising:
a circuit board, where a first die is disposed on the circuit board, a blank area is disposed on the circuit board, and a metal wire is disposed on a surface of the blank area;
the package structure according to claim 1, disposed on the circuit board, wherein a blank region in the package structure corresponds to the blank area; and
a second die, disposed on the package structure;
wherein the first die is electrically connected to the second die through the metal wire.
